(19) United States
(12) Patent Application Publication
(10) Pub. No.: US 2025/0347993 A1
(43) Pub. Date: Nov. 13, 2025

(54) SHAPING APPARATUS, SHAPING METHOD, AND ARTICLE MANUFACTURING METHOD

(71) Applicant: CANON KABUSHIKI KAISHA, Tokyo (JP)

(72) Inventors: TAKEHIKO UENO, Tochigi (JP); KIYOHITO YAMAMOTO, Tochigi (JP); YU NOMURA, Tochigi (JP)

(21) Appl. No.: 19/193,294

(22) Filed: Apr. 29, 2025

(30) Foreign Application Priority Data
May 9, 2024 (JP) 2024-076692

(51) Int. Cl. G03F 7/00; G03F 7/20; H01L 21/56

(52) U.S. Cl. CPC G03F 7/0002; G03F 7/2022; H01L 21/565

(57) ABSTRACT

The present invention provides a shaping apparatus that performs, for each of a plurality of regions on a substrate, processing of aligning a mold with the substrate while the mold is in contact with a composition on the substrate and then curing the composition to shape the composition, wherein the plurality of regions includes a first region where the processing is performed while a concentration of the first gas around the mold is adjusted to a first concentration and a second region where the concentration of the first gas around the mold is adjusted to a second concentration larger than the first concentration, preliminary exposure in the second region is controlled to make an integrated irradiation amount of light to the composition larger than in preliminary exposure in the first region.

### BACKGROUND OF THE INVENTION

### Field of the Invention

The present invention relates to a shaping apparatus, a shaping method, and an article manufacturing method.

### Description of the Related Art

With a growing demand for the miniaturization of semiconductor devices and the like, imprint techniques have been further developed. An imprint technique is a microfabrication technique of forming the pattern formed of the cured material of an imprint material on a substrate by performing the imprint processing of shaping the imprint material (composition) on the substrate using a mold having a concave-convex pattern. Using such an imprint technique can form a fine structure on a several nanometer order on the substrate. For example, one of the methods of curing an imprint material in imprint processing is a photo-curing method. In imprint processing using the photo-curing method, an imprint material on a substrate is cured by light irradiation upon alignment between a mold and the substrate while the mold and the imprint material are in contact with each other, and the mold is separated from the cured imprint material. This makes it possible to form the pattern of the imprint material on the substrate.

In imprint processing, there is a need to quickly fill the concave-convex pattern of a mold with an imprint material when bringing the mold into contact with the imprint processing on the substrate. Japanese Patent No. 6761329 proposes a method of supplying a gas (filling gas) for promoting filling with an imprint material, such as helium, to between a mold and a substrate when bringing the mold into contact with the imprint material on the substrate.

In bringing a mold into contact with an imprint material on a substrate, the viscosity of the imprint material is preferably low in terms of the filling property of the imprint material with respect to the concave-convex pattern of the mold. In alignment between a mold and a substrate which is performed while the mold is in contact with an imprint material on the substrate, if the viscosity of the imprint material is low, the alignment tends to be influenced by disturbance such as vibration from the floor on which an imprint apparatus is installed, and the alignment accuracy can deteriorate. Japanese Patent Laid-Open No. 2020-47944 proposes a method of improving the alignment accuracy of alignment between a mold and a substrate by performing preliminary exposure to increase the viscosity of an imprint material on a substrate by irradiating the imprint processing with light.

Imprint processing is performed for each of a plurality of shot regions on a substrate. Recently, imprint processing is required to be performed for even a shot region including an outer edge portion of a substrate (a so-called partial shot region) in order to improve the yield of product chips obtained from the substrate. Warpage or a stepped portion is sometimes formed on an outer edge portion of a substrate. At such an outer edge portion and its neighbor, the concave-convex pattern of the mold is insufficiently filled with the imprint material, and hence the imprint material sometimes remains in the mold after the imprint processing. The imprint material adhering to the mold kept in a cured state can be a factor that causes a defect in the pattern formed on the imprint material on the substrate in imprint processing for the succeeding shot region.

As a method of keeping an imprint material adhering to a mold in an uncured state, there is available a method of increasing the concentration of oxygen that inhibits a curing reaction of the imprint material. However, in this method, it is difficult to increase the viscosity of an imprint material to a desired viscosity due to oxygen in preliminary exposure. This can lead to a deterioration in alignment accuracy between the mold and the substrate.

### SUMMARY OF THE INVENTION

The present invention provides, for example, a technique advantageous in accurately shaping a composition on a substrate by using a mold.

According to one aspect of the present invention, there is provided a shaping apparatus that performs, for each of a plurality of regions on a substrate, processing of aligning a mold with the substrate while the mold is in contact with a composition on the substrate and then curing the composition to shape the composition, the apparatus comprising: a light irradiator configured to irradiate the composition with light; and a controller configured to control the processing, wherein the composition has a property of being inhibited from undergoing a curing reaction by a first gas, the plurality of regions includes a first region where the processing is performed while a concentration of the first gas around the mold is adjusted to a first concentration and a second region where the concentration of the first gas around the mold is adjusted to a second concentration larger than the first concentration, the processing includes preliminary exposure that increases a viscosity of the composition by causing the light irradiator to irradiate the composition with light for the alignment, and the controller controls the preliminary exposure in the second region so as to make an integrated irradiation amount of light to the composition larger than in the preliminary exposure in the first region.

Further features of the present invention will become apparent from the following description of exemplary embodiments with reference to the attached drawings.

### BRIEF DESCRIPTION OF THE DRAWINGS

FIG. 1 is a view showing an example of the arrangement of an imprint apparatus according to an embodiment of the present invention;

FIG. 2 is a view showing an example of the layout of a plurality of shot regions on a substrate;

FIG. 3 is a flowchart showing an example of the operation of the imprint apparatus;

FIGS. 4A and 4B are views for explaining the adhesion of an imprint material to a mold;

FIG. 5 is a flowchart showing an integrated irradiation amount determination method;

FIG. 6 is a graph showing an example of second information indicating the relationship between oxygen concentration and integrated irradiation amount; and

FIGS. 7A to 7F are views for explaining an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. Control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or posture. Alignment can include controlling the position and/or posture of at least one of a substrate and a mold such that the alignment error (overlay error) between the shot region of the substrate and the pattern region of the mold decreases. Alignment may include control to correct or change the shape of at least one of the shot region of the substrate and the pattern region of the mold.

A shaping apparatus according to the present invention is an apparatus that performs the shaping processing of shaping a composition on a substrate by pressing a mold against the composition. Examples of the shaping apparatus include an imprint apparatus and a planarization apparatus. The imprint apparatus is an apparatus that brings a mold having a concave-convex pattern into contact with an uncured composition (imprint material) supplied onto a substrate and gives curing energy to the composition, thereby forming, on the substrate, the pattern of the cured material onto which the pattern of the mold is transferred.

Shaping processing performed by the imprint apparatus is sometimes called imprint processing. The planarization apparatus is an apparatus that brings a mold having a flat surface into contact with an uncured composition supplied onto a substrate and gives curing energy to the composition, thereby forming a cured material having a flat surface on the substrate (that is, planarizing the surface of the composition on the substrate). Shaping processing performed by the planarization apparatus is sometimes called planarization processing. The following will exemplify an imprint apparatus as a shaping apparatus. However, the arrangement/processing of the imprint apparatus can also be applied to a planarization apparatus.

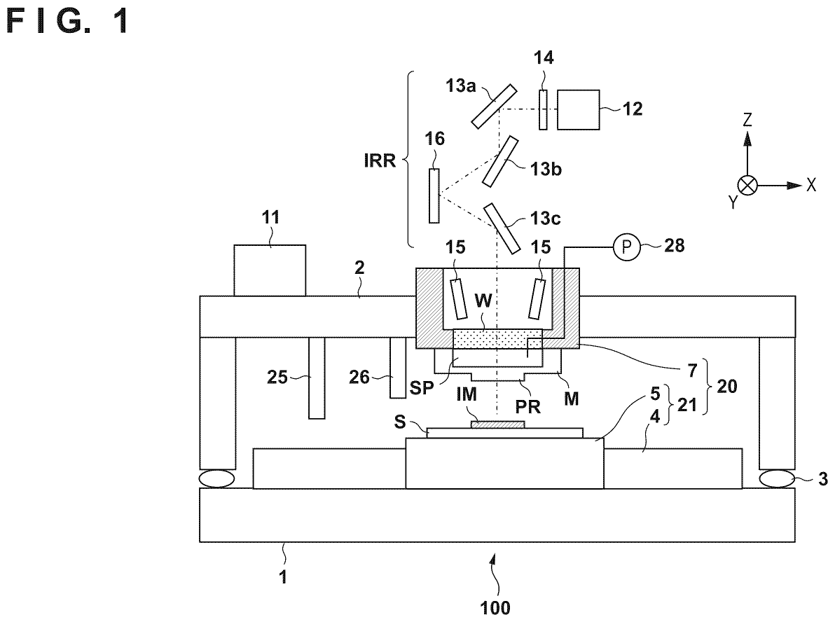

FIG. 1 schematically shows an example of the arrangement of an imprint apparatus 100 according to an embodiment of the present invention. The imprint apparatus 100 is a lithography apparatus that shapes an imprint material IM (composition) on a substrate S by using a mold M and can be used in a lithography process as a device manufacturing process for semiconductor devices and magnetic storage media. The imprint apparatus 100 performs the processing of shaping the imprint material IM on the substrate S by bringing the mold M into contact with the imprint material IM on the substrate S and curing the imprint material IM upon alignment between the mold M and the substrate S in this state. Such processing is called imprint processing and is performed for each of a plurality of shot regions (imprint regions) on the substrate S. The present embodiment exemplifies a photo-curing method of curing the imprint material IM on the substrate S by irradiating the imprint material IM with light (for example, ultraviolet light).

As the imprint material IM, a curable composition (to be also referred to as a resin in an uncured state hereinafter) to be cured by receiving curing energy is used. As the curing energy, electromagnetic waves, heat, or the like can be used. As the electromagnetic waves, light such as infrared light, visible light, or ultraviolet light selected from the wavelength range of 10 nm (inclusive) to 1 mm (inclusive) can be used. The curable composition can be a composition cured by light irradiation or heating. Among these, the photo-curable composition cured by light irradiation contains at least a polymerizable compound and a photopolymerization initiator, and may contain a nonpolymerizable compound or a solvent, as needed. The nonpolymerizable compound is at least one type of material selected from a group consisting of a sensitizer, a hydrogen donor, an internal mold release agent, a surfactant, an antioxidant, a polymer component, and the like. The imprint material IM may be arranged on the substrate S in the form of droplets or in the form of an island or film formed by connecting a plurality of droplets. The viscosity (the viscosity at 25° C.) of the imprint material IM can be, for example, 1 mPa·s (inclusive) to 100 mPa·s (inclusive).

As a material for the substrate S, for example, glass, ceramic, metal, semiconductor, resin, or the like is used. The surface of the substrate S may be provided with a member made of a material different from the substrate S as needed. The substrate S is, for example, a silicon wafer, compound semiconductor wafer, or silica glass. The mold M generally has a rectangular outer peripheral shape and is manufactured by a material that can transmit light (ultraviolet light), such as silica glass. A partial region of the surface of the mold M which faces the substrate S is provided with a mesa portion PR formed into a mesa shape having a level difference of about several tens of nm. The surface of the mesa portion PR on the substrate S side functions as a shaping surface (contact surface) which comes into contact with the imprint material IM on the substrate S to shape the imprint material IM. The shaping surface of the mold M used in the imprint apparatus 100 is formed as a pattern surface on which a concave-convex pattern to be transferred to the imprint material IM on the substrate S, such as a circuit pattern, is three-dimensionally formed. In the following description, the region of the mold M on which a concave-convex pattern is formed (that is, the mesa portion PR) will sometimes be referred to as the “pattern region PR”. Note that the shaping surface of the mold M used in a planarization apparatus is formed as a flat surface whose 90% or more (preferably 95% or more) of the region has no concave-convex pattern.

The imprint apparatus 100 can include a base plate 1, a dumper 3, a frame 2, a relative drive mechanism 20, a shape adjusting mechanism 28, a light irradiator IRR, an alignment scope 15, a dispenser 25, a concentration adjuster 26, and a controller 11.

The relative drive mechanism 20 changes the relative position between a shot region on the substrate S and the pattern region PR of the mold M. Changing the relative position by the relative drive mechanism 20 includes driving for bringing the mold M into contact with the imprint material IM on the substrate S and separating the mold M from the cured imprint material IM (the pattern of the cured material). In addition, changing the relative position by the relative drive mechanism 20 includes alignment between the substrate S (shot region) and the mold M (the pattern region PR). The relative drive mechanism 20 can include a substrate positioning mechanism 21 that positions the substrate S (shot region) and a mold positioning mechanism 7 that positions the mold M (the pattern region PR).

The substrate positioning mechanism 21 can include a substrate holder 5 that holds the substrate S and a substrate drive mechanism 4 that drives the substrate S by driving the substrate holder 5. The substrate holder 5 and the substrate drive mechanism 4 can be supported by the base plate 1. The substrate drive mechanism 4 can be configured to drive the substrate S along a plurality of axes (for example, three axes including the X-axis, Y-axis, and θZ-axis, preferably six axes including the X-axis, Y-axis, Z-axis, θX-axis, θY-axis, and θZ-axis). The imprint apparatus 100 can include a measuring instrument (for example, an interferometer or encoder) that measures the position of the substrate S or the substrate holder 5. This makes it possible to perform feedback control of the position of the substrate holder 5 based on an output from the measuring instrument.

The mold positioning mechanism 7 can include a mold holder (not shown) that holds the mold M and a mold drive mechanism (not shown) that drives the mold M by driving the mold holder. The mold positioning mechanism 7 can be configured to drive the mold M along a plurality of axes (for example, three axes including the Z-axis, θX-axis, and θY-axis, preferably six axes including the X-axis, Y-axis, Z-axis, θX-axis, θY-axis, and θZ-axis). In this case, the frame 2 can be provided on the base plate 1 through the dumper 3. The dumper 3 reduces the transmission of vibration from the base plate 1 to the frame 2. The mold positioning mechanism 7 can be supported by the frame 2.

The imprint apparatus 100 can further include the shape adjusting mechanism 28 that adjusts the shape of the pattern region PR so as to increase the contact area between the imprint material IM and the pattern region PR after partial contact between the imprint material IM on the substrate S and the pattern region PR of the mold M. The shape adjusting mechanism 28 can adjust the shape of the pattern region PR by adjusting the pressure of a space SP formed on the reverse surface (the opposite surface to the pattern region PR) of the mold M. The pattern region PR of the mold M can be formed into a convex shape toward the substrate S or a flat shape by the shape adjusting mechanism 28.

The light irradiator IRR is configured to irradiate the imprint material IM on the substrate S with light (in other words, to expose the imprint material IM to light). The mold positioning mechanism 7 has a window W that transmits light from the light irradiator IRR and defines the space SP. The light irradiator IRR can be configured to irradiate the imprint material IM on the substrate S to light through the window W.

The light irradiator IRR according to the present embodiment can include a light source 12, a shutter 14, mirrors 13a, 13b, and 13c, and a spatial light modulator 16. The spatial light modulator 16 can control the illuminance distribution of light applied to the imprint material IM on the substrate S in accordance with a command from the controller 11. The spatial light modulator 16 can be implemented by, for example, a digital mirror device (DMD). The digital mirror device includes a plurality of mirrors that can be individually controlled and can control the illuminance distribution of light applied to the imprint material IM on the substrate S by setting the respective angles of the plurality of mirrors. In place of the spatial light modulator 16, for example, a liquid crystal spatial light modulator can be used.

Irradiation of the imprint material IM on the substrate S with light, that is, exposure of the imprint material IM, includes preliminary exposure and main exposure. The light irradiator IRR according to the present embodiment can be used for preliminary exposure and main exposure. The aim of preliminary exposure is to increase the viscosity of the imprint material IM to a target viscosity by irradiating the imprint material IM on the substrate S with light for alignment between the mold M and the substrate S while the mold M is in contact with the imprint material IM on the substrate S. A target viscosity can be set to reduce the relative vibration caused by disturbance between the mold M and the substrate S while ensuring the fluidity that allows the relative drive mechanism 20 to relatively drive the mold M and the substrate S. The disturbance can include, for example, vibration transmitted from the floor on which the imprint apparatus 100 is installed to the imprint apparatus 100. In addition, the main exposure is the operation of curing (solidifying) the imprint material IM to a target hardness by irradiating the imprint material IM on the substrate S with light after the end of alignment between the mold M and the substrate S. The target hardness can be set to allow the pattern of the imprint material IM to maintain its shape without having fluidity even after the separation of the mold M.

The light irradiator IRR may have a plurality of light sources with different emission wavelengths and/or emission intensities. For example, for preliminary exposure, at least one corresponding light source can be used, whereas for main exposure, at least one corresponding light source can be used. In this case, a common spatial light modulator may be provided for a plurality of light sources or a plurality of spatial light modulators may be respectively provided for a plurality of light sources. Assume that in this case, the light source 12 of the light irradiator IRR has a light output that can obtain the viscosity of the imprint material IM which is required to control alignment between the mold M and the substrate S (overlay control) with respect to the concentration (including zero) of a filling gas.

The alignment scope 15 (detector) is used to detect an alignment error (overlay error) between a shot region on the substrate S and the pattern region PR of the mold M. The alignment scope 15 can be configured to detect the relative position between a mark provided on the shot region on the substrate S and a mark provided on the pattern region PR of the mold M. Detecting the relative positions between a plurality of mark pairs using the alignment scope 15 can detect an alignment error between the shot region on the substrate S and the pattern region PR of the mold M. Each mark pair can be constituted by a mark provided on a shot region and a mark provided on the pattern region PR. The imprint apparatus 100 uses a die-by-die alignment scheme as an alignment method for a shot region on the substrate S and the pattern region PR of the mold M.

The dispenser 25 (supplier) places (supplies) the imprint material IM on the substrate S. The dispenser 25 may be configured or controlled to place the imprint material IM on a plurality of shot regions on the substrate S. The imprint material IM can be placed on the substrate S by being discharged in the form of droplets from the dispenser 25 while the substrate S is scanned or driven by the substrate positioning mechanism 21. The imprint material IM may be placed on the substrate S by an external device of the imprint apparatus 100, and the substrate S on which the imprint material IM is placed may be provided onto the substrate S. In this case, the imprint apparatus 100 need not be provided with the dispenser 25.

The concentration adjuster 26 (adjuster) adjusts the concentration of a first gas around the mold M (the pattern region PR). The concentration adjuster 26 according to the present embodiment can adjust the concentration of the first gas to around the mold M by supplying a second gas different from the first gas around the mold M (the pattern region PR). The imprint material IM has the property of being inhibited from undergoing a curing reaction (that is, an increase in viscosity) by the first gas. As the first gas, oxygen is available. The following description will exemplify oxygen as the first gas. However, the first gas is not limited to oxygen, and any gas that inhibits the imprint material IM from being cured can be used. In addition, the second gas can be a gas that has a lower oxygen concentration than air. As the second gas, it is possible to use a gas that can suppress (reduce) the inhibition of curing of the imprint material IM by oxygen (to be sometimes referred to as a filling gas hereinafter) while improving the filling property of the imprint material IM with respect to the concave-convex pattern of the mold M. As a filling gas, it is possible to use, for example, a gas including at least one of helium gas, nitrogen gas, and condensable gas (for example, pentafluoropropane gas (PFP)). The filling gas supplied around the mold M can be transported to below the pattern region PR of the mold M, for example, to between the pattern region PR of the mold M and the substrate S by the movement of the substrate S.

The controller 11 is implemented by, for example, a computer (information processing apparatus) having a processor such as a Central Processing Unit (CPU) and a storage unit such as a memory. The controller 11 controls imprint processing by controlling the respective units of the imprint apparatus 100. For example, the controller 11 can be configured to control the relative drive mechanism 20, the shape adjusting mechanism 28, the light irradiator IRR, the alignment scope 15, the dispenser 25, and the concentration adjuster 26. The controller 11 may be implemented by, for example, a Programmable Logic Device (PLD) such as a Field Programmable Gate Array (FPGA), an Application Specific Integrated Circuit (ASIC), a general-purpose or dedicated computer incorporating programs, or a combination of all or some of these components.

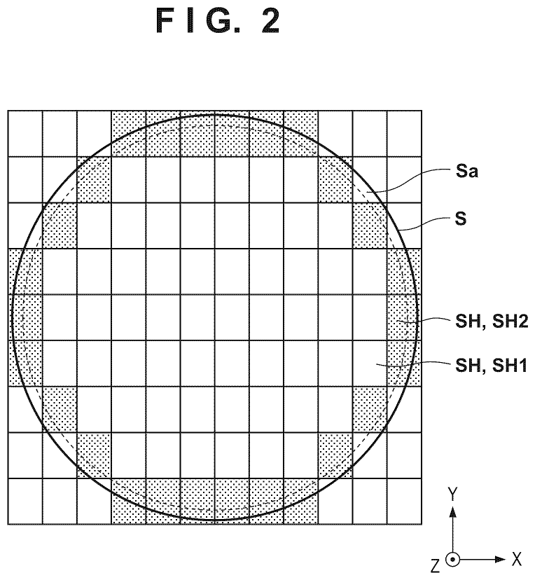

The imprint apparatus 100 having the above arrangement sequentially executes imprint processing for each of shot regions SH on the substrate S. FIG. 2 shows an example of the layout of the plurality of shot regions SH on the substrate S. As shown in FIG. 2, the respective shot regions on the substrate S can be roughly classified into full shot regions SH1 and partial shot regions SH2. The full shot region SH1 is the shot region SH (the first region) that is placed in the central area of the substrate S and does not include an outer edge portion Sa (edge) of the substrate S. The overall concave-convex pattern provided on the pattern region PR of the mold M is transferred to the full shot regions SH1. The partial shot region SH2 is the shot region SH (the second region) that is placed in a peripheral area of the substrate S and has the outer edge portion Sa (edge) of the substrate S. Only part of the concave-convex pattern provided on the pattern region PR of the mold M is transferred to the partial shot regions SH2. Recently, in order to improve the yield of product chips obtained from the substrate S, imprint processing is required to be performed even for the partial shot region SH2 having the outer edge portion Sa of the substrate S. Note that the full shot region SH1 is sometimes called a complete shot region or central shot region. The partial shot region SH2 is sometimes called a deficient shot region or peripheral shot region.

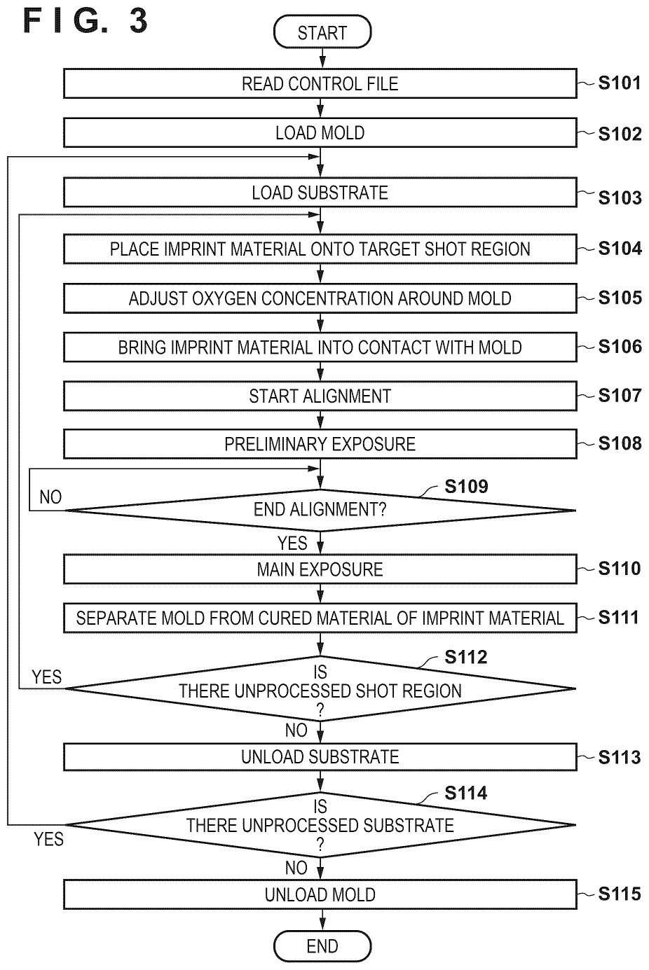

An operation procedure of the imprint apparatus 100 according to the present embodiment will be described next. FIG. 3 is a flowchart showing an example of the operation of the imprint apparatus 100 according to the present embodiment. The flowchart of FIG. 3 shows an example of sequentially performing imprint processing for the plurality of shot regions SH on each of one or more substrates S and can be executed by the controller 11. The imprint processing can include steps S104 to S111 in the flowchart of FIG. 3.

In step S101, the controller 11 reads a control file from a memory or device (not shown). This control file can include information indicating the layout (array) of the plurality of shot regions SH on the substrate S, information for controlling preliminary exposure, information for controlling main exposure, and information specifying the position at which the dispenser 25 places the imprint material IM.

In step S102, the controller 11 controls a mold transfer mechanism (not shown) and the mold positioning mechanism 7 so as to load the mold M and make the mold holder of the mold positioning mechanism 7 hold the mold M. In step S103, the controller 11 controls a substrate transfer mechanism (not shown) and the substrate positioning mechanism 21 so as to load the substrate S and make the substrate holder 5 hold the substrate S.

In step S104, the controller 11 places (supplies) the imprint material IM onto a shot region, of the plurality of shot regions SH, to which imprint processing is to be performed (to be sometimes referred to as the target shot region SH hereinafter). In the present embodiment, the controller 11 causes the dispenser 25 to discharge the imprint material IM in the form of droplets while causing the substrate positioning mechanism 21 (the substrate drive mechanism 4) below the dispenser 25 to move the substrate S in the X and Y directions. This makes it possible to place (supply) the imprint material IM in the form of droplets onto the target shot region SH. Note that if the imprint material IM is placed on the substrate S by an external device of the imprint apparatus 100, step S104 can be omitted.

In step S105, the controller 11 controls the concentration adjuster 26 to adjust the oxygen concentration around the mold M (the pattern region PR) to a target concentration. In the present embodiment, the concentration adjuster 26 is configured to adjust the oxygen concentration around the mold M by supplying a filling gas around the mold M (the pattern region PR), for example, between the mold M (the pattern region PR) and the substrate S (the target shot region SH). The controller 11 controls the supply amount of filling gas from the concentration adjuster 26 so as to adjust the oxygen concentration around the mold M (the pattern region PR) to a target concentration. In this case, a target concentration can be set in advance for each shot region SH. The supply amount of filling gas from the concentration adjuster 26 can be determined in accordance with a target concentration set in advance. If, however, the concentration adjuster 26 is provided with a sensor that detects the oxygen concentration around the mold M, the concentration adjuster 26 may be controlled to adjust the oxygen concentration detected by the sensor to a target concentration. In the present embodiment, the oxygen concentration (target concentration) around the mold M in imprint processing is changed between the full shot region SH1 and the partial shot region SH2. For example, imprint processing is performed for the full shot region SH1 while the oxygen concentration around the mold M is adjusted to the first concentration. In contrast to this, imprint processing is performed for the partial shot region SH2 while the oxygen concentration around the mold M is adjusted to the second concentration larger than the first concentration. In this case, the supply amount of filling gas in imprint processing for the partial shot region SH2 can be controlled to be smaller than the supply amount of filling gas in imprint processing for the full shot region SH1. Note that the concentration adjuster 26 may not supply any filling gas in imprint processing for the partial shot region SH2.

In step S106, the controller 11 controls the relative drive mechanism 20 and the shape adjusting mechanism 28 so as to bring the imprint material IM on the target shot region SH into contact with the pattern region PR of the mold M. In the present embodiment, the controller 11 controls the relative driving between the mold M and the substrate S in the Z direction by the relative drive mechanism 20 so as to reduce the interval between the target shot region SH on the substrate S and the pattern region PR of the mold M. The controller 11 controls the adjustment of the shape of the pattern region PR by the shape adjusting mechanism 28 so as to increase the contact area between the imprint material IM and the pattern region PR after part of the pattern region PR of the mold M comes into contact with the imprint material IM on the target shot region SH.

In step S107, the controller 11 starts the operation of controlling the relative drive mechanism 20 so as to reduce the alignment error between the target shot region SH and the pattern region PR of the mold M while detecting the alignment error with the alignment scope 15. This operation is sometimes referred to as an alignment operation hereinafter. In the present embodiment, the controller 11 controls the relative driving between the mold M and the substrate S in the X and Y directions by the relative drive mechanism 20 so as to reduce the alignment error based on the detection result obtained by the alignment scope 15.

In step S108, the controller 11 controls the light irradiator IRR so as to perform preliminary exposure to increase the viscosity of the imprint material IM to a target viscosity by irradiating the imprint material IM on the target shot region SH with light. Increasing the viscosity (viscoelasticity) of the imprint material IM by preliminary exposure will join the substrate S to the mold M with the imprint material IM and reduce the relative vibration between the substrate S and the mold M while the mold M is in contact with the imprint material IM. This makes it possible to improve the alignment accuracy between the target shot region SH on the substrate S and the pattern region PR of the mold M. In the present embodiment, step S108 is performed after step S107. However, limitation is not made thereto, and step S108 may be performed before step S107 or between step S106 and step S107.

In this case, preliminary exposure is executed under a condition (for example, an illuminance distribution) that enables filling of a recess portion of the pattern region PR of the mold M or a space between the substrate S and the pattern region PR with the imprint material IM sufficiently throughout the entire shot region. Preliminary exposure may be divisionally executed a plurality of times. In the present embodiment, the controller 11 controls (changes) the integrated irradiation amount of light applied to the imprint material IM on the target shot region SH by the light irradiator IRR in preliminary exposure in accordance with the oxygen concentration around the mold M (the pattern region PR). A method (control method) of determining an integrated irradiation amount will be described later.

In step S109, the controller 11 determines whether the alignment operation started in step S107 is terminated. If the controller 11 determines that the alignment operation is terminated, the process advances to step S110. In contrast, if the controller 11 determines that the alignment operation is not terminated, the alignment operation is repeated. The controller 11 determines again in step S109 whether the alignment operation is terminated. If, for example, the alignment error detected by using the alignment scope 15 falls within an allowable range, the controller 11 can determine that the alignment operation is terminated. Alternatively, the controller 11 may determine that the alignment operation is terminated, if a predetermined time has elapsed since the timing at which the alignment operation is started in step S107. In this case, the predetermined time can be set so as to obtain sufficiently high alignment accuracy. In the present embodiment, a period in which an alignment operation is performed can include a period in which the imprint material IM is not irradiated with light after the end of preliminary exposure. That is, part of an alignment operation can be performed in the interval from the end of preliminary exposure to the start of main exposure.

In step S110, the controller 11 controls the light irradiator IRR to perform main exposure to cure the imprint material IM on the target shot region SH to a target hardness by further irradiating the imprint material IM with light. In the main exposure, the imprint material IM is irradiated with light so as to enable separation between the cured material of the imprint material IM and the mold M, for example, to make the irradiation amount of light to the imprint material IM become a specified irradiation amount throughout the entire target shot region SH. In step S111, the controller 11 controls the relative drive mechanism 20 to separate the mold M from the imprint material IM on the target shot region SH. In the present embodiment, the controller 11 controls the relative driving between the mold M and the substrate S in the Z direction by the relative drive mechanism 20 so as to increase the interval between the target shot region SH on the step S and the pattern region PR of the mold M in the Z direction. With this operation, the cured material of the imprint material IM onto which the concave-convex pattern of the mold M is transferred is formed on the target shot region SH.

In step S112, the controller 11 determines whether there is any shot region SH for which imprint processing has not been performed (to be referred to as the unprocessed shot region SH hereinafter) on the substrate S. If there is the unprocessed shot region SH, the controller 11 executes imprint processing (steps S104 to S111) for the unprocessed shot region SH as the target shot region SH. In contrast, if there is not the unprocessed shot region SH, that is, imprint processing for all the shot regions SH is completed, the controller 11 advances the process to step S113. In step S113, the controller 11 controls the substrate transfer mechanism (not shown) and the substrate positioning mechanism 21 to unload the substrate S from the substrate holder 5.

In step S114, the controller 11 determines whether there is any substrate S for which imprint processing has not been performed (to be referred to as the unprocessed substrate S hereinafter). If there is the unprocessed substrate S, the controller 11 executes steps S103 to S111 for the unprocessed substrate S. In contrast, if there is not the unprocessed substrate S, that is, imprint processing for all the substrates S is completed, the controller 11 advances the process to step S115. In step S115, the controller 11 controls the mold transfer mechanism (not shown) and the mold positioning mechanism 7 to unload the mold M from the mold holder of the mold positioning mechanism 7. This ends the series of processing (operation procedure) exemplified in FIG. 3.

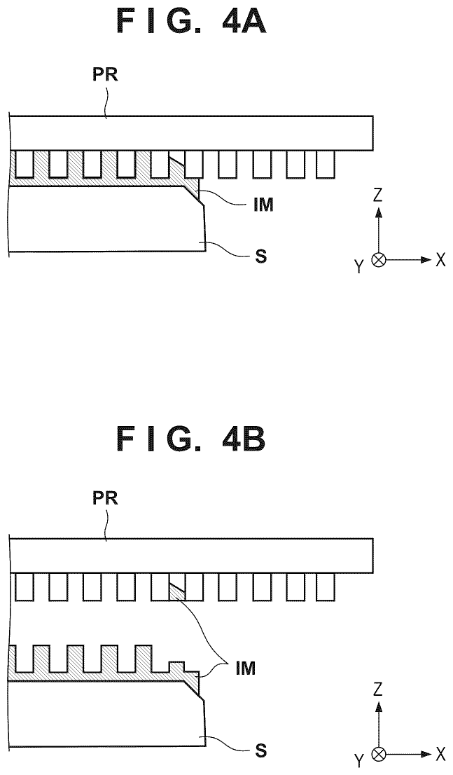

Warpage or a stepped portion is sometimes formed on an outer edge portion Sa of the substrate S or chamfering (beveling) is sometimes applied to the outer edge portion Sa. As shown in FIG. 4A, in imprint processing for the partial shot region SH2 including the outer edge portion 2a, filling of the concave-convex pattern of the mold M with the imprint material IM can be insufficient at or near the outer edge portion 2a. As a result, as shown in FIG. 4B, part of the imprint material IM sometimes keeps adhering to the pattern region PR of the mold M after imprint processing. The cured imprint material IM adhering to the mold M can be a factor that causes a pattern defect in imprint processing for the succeeding shot region SH.

As one method of keeping the imprint material IM adhering to the mold M in the uncured state, there is presented a method including adjusting the oxygen concentration around the mold M in imprint processing. More specifically, as described with reference to step S105, in imprint processing for the partial shot region SH2, the oxygen concentration around the mold M is increased as compared with imprint processing for the full shot region SH1. Since the imprint material IM has the property of being inhibited from undergoing a curing reaction by oxygen, it is possible to avoid of the imprint material IM from adhering (remaining) to the pattern region PR of the mold M in the cured state in imprint processing for the partial shot region SH2. That is, even if the imprint material IM adheres to the pattern region PR of the mold M due to imprint processing for the partial shot region SH2, the imprint material IM can be made to remain in the pattern region PR in the uncured state. The imprint material IM remaining in the pattern region PR of the mold M in the uncured state is integrated (mixed, merged, or fused) with the imprint material IM on the shot region SH for which imprint processing is performed later. This makes it possible to remove the imprint material IM remaining in the pattern region PR of the mold M and reduce the occurrence of pattern defects in imprint processing for the succeeding shot region SH.

In this method, however, since oxygen inhibits an increase in the viscosity of the imprint material IM in preliminary exposure to the partial shot region SH2, it is difficult to increase the viscosity of the imprint material IM to a target viscosity. This can lead to a deterioration in the alignment accuracy between the mold M and the substrate S. For this reason, the controller 11 according to the present embodiment controls the integrated irradiation amount of light applied to the imprint material IM by the light irradiator IRR in preliminary exposure. More specifically, the controller 11 controls preliminary exposure for the partial shot region SH2 such that the integrated irradiation amount of light on the imprint material IM becomes larger than that in preliminary exposure for the full shot region SH1. The integrated irradiation amount can be understood as the integration of irradiation amounts (light amounts) per unit area. This makes it possible to effectively perform preliminary exposure in imprint processing for the partial shot region SH, thereby improving the alignment accuracy.

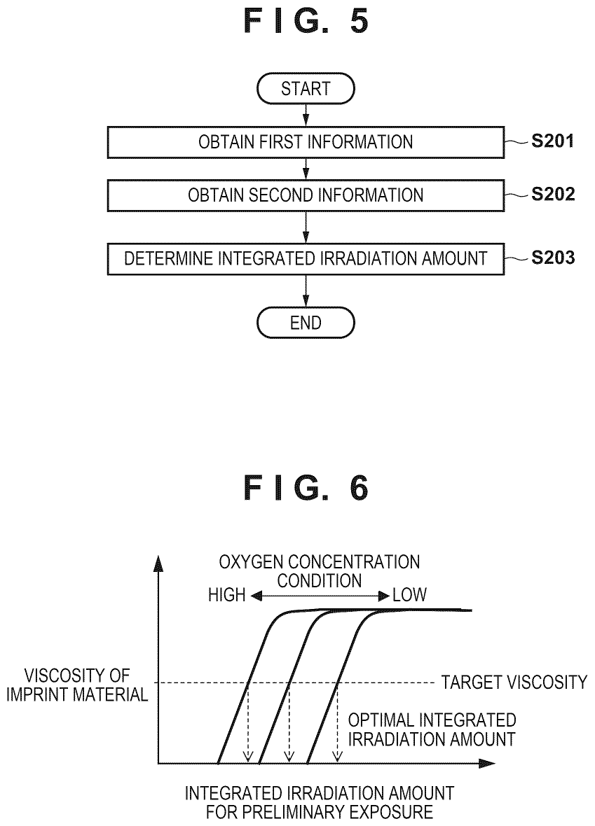

An integrated irradiation amount determination method will be described next. FIG. 5 is a flowchart showing the integrated irradiation amount determination method. The controller 11 can execute the flowchart of FIG. 5. An integrated irradiation amount may be determined for each shot region SH or may be determined for the two types of shot regions, namely the full shot region SH1 and the partial shot region SH2.

In step S201, the controller 11 obtains first information indicating the oxygen concentration around the mold M in imprint processing. The first information can be information indicating a target concentration (set concentration) set in advance with respect to an oxygen concentration around the mold M in imprint processing. Alternatively, the first information may be information indicating the oxygen concentration detected by a sensor for detecting an oxygen concentration around the mold M if the sensor is provided.

In step S202, the controller 11 obtains the second information indicating the relationship between oxygen concentration and integrated irradiation amount for increasing the viscosity of the imprint material IM to a target viscosity in preliminary exposure. The second information is created in advance by experiments, simulations, and the like and stored in a memory or device (not shown). The controller 11 reads the second information from the memory or device (not shown). FIG. 6 shows an example of the second information. According to the example of the second information shown in FIG. 6, the relationship between the integrated irradiation amount of light to the imprint material IM in preliminary exposure and the viscosity of the imprint material IM is presented for each oxygen concentration condition. In this case, the example of the second information shown in FIG. 6 shows the relationships between the integrated irradiation amount and the viscosity of the imprint material IM for three types of oxygen concentration conditions. These relationships may be specified for two types or four types or more of oxygen concentration conditions.

In step S203, the controller 11 determines an integrated irradiation amount based on the first information obtained in step S201 and the second information obtained in step S202. For example, in the second information shown in FIG. 6, the controller 11 selects the relationship specified by the oxygen concentration condition closest to the oxygen concentration of the first information obtained in step S201 from the relationships between the integrated irradiation amounts specified for the respective oxygen concentration conditions and the viscosities of the imprint material IM. This enables the controller 11 to determine an integrated irradiation amount (optimal integrated irradiation amount) for setting the viscosity of the imprint material IM to a target viscosity in preliminary exposure based on the selected relationship.

The integrated irradiation amount determined in this manner can be reflected in step S108 (preliminary exposure). In step S108, the controller 11 controls preliminary exposure performed by the light irradiator IRR based on the integrated irradiation amount determined through steps S201 to S203. The controller 11 may control the integrated irradiation amount for preliminary exposure in accordance with the irradiation intensity (illuminance) of light to the imprint material IM by the light irradiator IRR or in accordance with the irradiation time of light to the imprint material IM by the light irradiator IRR. Alternatively, the controller 11 may control the integrated irradiation amount for preliminary exposure based on the on/off duty ratio of light to the imprint material IM by the light irradiator IRR.

In this case, an integrated irradiation amount can be expressed by equation (1) given below. In equation (1), the irradiation area (irradiation region) of light can be specified by the minimum resolution of the spatial light modulator 16 (for example, a digital mirror device) of the light irradiator IRR. For example, if the irradiation area is divided into 20 partial regions (vertical 5×horizontal 4), with the irradiation intensity of each partial region being 5, and the irradiation time being 1, the integrated irradiation amount is 100.

integrated irradiation amount=irradiation region (vertical×horizontal)×irradiation intensity×irradiation time (1)

The integrated irradiation amount changes depending on the type of photopolymerization reaction of the imprint material IM and can be represented by equation (2) given below in the case of another type of imprint material IM.

integrated irradiation amount=irradiation region (vertical×horizontal)×(√irradiation intensity)×irradiation time (2)

In this case, the irradiation time in equations (1) and (2) is equal to or less than the time allocated to preliminary exposure based on the design value of the throughput of the imprint apparatus 100. In addition, the maximum output of the light irradiator IRR (the light source 12) is set to obtain a light amount equal to or more than the light amount with which an increase in the viscosity of the imprint material IM required for an alignment operation is obtained in the irradiation time or less in a case where the concentration of filling gas is zero. The irradiation intensity (illuminance) can be controlled by, for example, adjusting the angle of each mirror of the digital mirror device in the spatial light modulator 16 of the light irradiator IRR and adjusting the on/off ratio of light applied to the imprint material IM.

As described above, in the imprint apparatus 100 according to the present embodiment, preliminary exposure to the partial shot region SH2 is controlled to set a larger integrated irradiation amount of light to the imprint material IM than in preliminary exposure to the full shot region SH1. This makes it possible to effectively perform preliminary exposure in imprint processing for the partial shot region SH and hence to improve the alignment accuracy. That is, it is possible to accurately shape the imprint material IM on the substrate S by using the mold M.

The present embodiment has exemplified the case where the oxygen concentration around the mold M in imprint processing and the integrated irradiation amount for preliminary exposure are changed between the full shot region SH1 and the partial shot region SH2. However, limitation is not made thereto. For example, the oxygen concentration around the mold M in imprint processing and the integrated irradiation amount for preliminary exposure may be changed between the two or more shot regions SH (the two or more partial shot regions SH2) with different sizes and/or shapes. For example, in imprint processing for the two partial shot regions SH2 with different sizes, the oxygen concentration around the mold M and the integrated irradiation amount for preliminary exposure in imprint processing for one of the partial shot regions SH2 which has a smaller size can be larger than those in imprint processing for the partial shot region SH2 having a larger size. That is, the partial shot region SH2 having a larger size can be specified as the first region, and the partial shot region SH2 having a smaller size can be specified as the second region.

### Embodiment of Article Manufacturing Method

An article manufacturing method according to an embodiment of the present invention is suitable for manufacturing an article, for example, a microdevice such as a semiconductor device or an element having a fine structure. The article manufacturing method according to this embodiment includes a shaping step of shaping a composition on a substrate using the above-described shaping apparatus (shaping method), a processing step of processing the substrate that has the composition shaped by the shaping step, and a manufacturing step of manufacturing an article from the substrate processed by the processing step. As the shaping apparatus, an imprint apparatus or a planarization apparatus can be used. The manufacturing method also includes other known steps (oxidation, deposition, vapor deposition, doping, planarization, etching, resist removal, dicing, bonding, packaging, and the like). The article manufacturing method according to this embodiment is advantageous in at least one of the performance, quality, productivity, and production cost of the article, as compared to conventional methods.

The pattern of a cured product shaped using the shaping apparatus described above is used permanently for at least some of various kinds of articles or temporarily when manufacturing various kinds of articles. The articles are an electric circuit element, an optical element, a MEMS, a recording element, a sensor, a mold, or the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. The mold includes an imprint mold or the like.

The pattern of the cured product is directly used as the constituent member of at least some of the above-described articles or used temporarily as a resist mask. After etching or ion implantation is performed in the substrate processing step, the resist mask is removed.

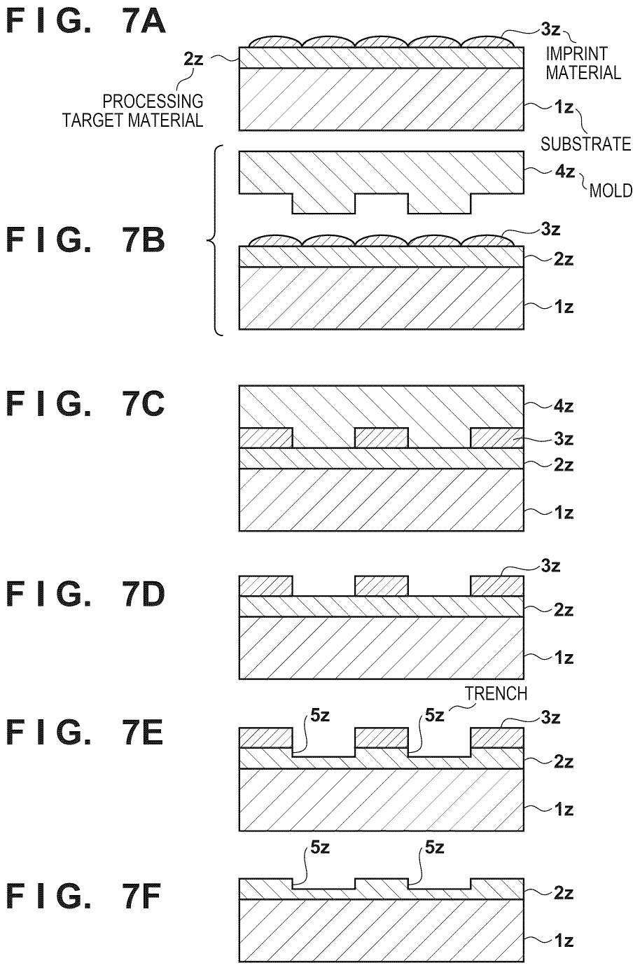

A practical article manufacturing method in a case where an imprint apparatus is used as a shaping apparatus will be described next. As shown FIG. 7A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 7B, a side of a mold 4z for imprint with a convex-concave pattern is directed to face the imprint material 3z on the substrate. As shown FIG. 7C, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

As shown in FIG. 7D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the convex-concave pattern of the mold 4z is transferred to the imprint material 3z.

As shown in FIG. 7E, when etching is performed using the pattern of the cured product as an etching resistant mask, a portion of the surface of the processed material 2z where the cured product does not exist or remains thin is removed to form a groove 5z. As shown in FIG. 7F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™M), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-076692 filed on May 9, 2024, which is hereby incorporated by reference herein in its entirety.

What is claimed is:

1. A shaping apparatus that performs, for each of a plurality of regions on a substrate, processing of aligning a mold with the substrate while the mold is in contact with a composition on the substrate and then curing the composition to shape the composition, the apparatus comprising:
a light irradiator configured to irradiate the composition with light; and
a controller configured to control the processing,
wherein the composition has a property of being inhibited from undergoing a curing reaction by a first gas,
the plurality of regions includes a first region where the processing is performed while a concentration of the first gas around the mold is adjusted to a first concentration and a second region where the concentration of the first gas around the mold is adjusted to a second concentration larger than the first concentration,
the processing includes preliminary exposure that increases a viscosity of the composition by causing the light irradiator to irradiate the composition with light for the alignment, and
the controller controls the preliminary exposure in the second region so as to make an integrated irradiation amount of light to the composition larger than in the preliminary exposure in the first region.

2. The apparatus according to claim 1, wherein the controller controls the preliminary exposure in the first region and the preliminary exposure in the second region based on information indicating a relationship between the concentration of the first gas and the integrated irradiation amount for increasing the viscosity of the composition to a target viscosity.

3. The apparatus according to claim 1, wherein a period in which the alignment is performed in the processing includes a period in which the composition is not irradiated with light after an end of the preliminary exposure.

4. The apparatus according to claim 1, wherein the controller controls the integrated irradiation amount in the preliminary exposure by an irradiation intensity of light applied to the composition by the light irradiator.

5. The apparatus according to claim 1, wherein the controller controls the integrated irradiation amount in the preliminary exposure by an irradiation time of light applied to the composition by the light irradiator.

6. The apparatus according to claim 1, wherein the controller controls the integrated irradiation amount in the preliminary exposure by an on/off duty ratio of light applied to the composition by the light irradiator.

7. The apparatus according to claim 1, further comprising an adjuster configured to adjust the concentration of the first gas around the mold.

8. The apparatus according to claim 7, wherein the adjuster adjusts the concentration of the first gas around the mold by supplying a second gas different from the first gas to around the mold.

9. The apparatus according to claim 8, wherein the controller controls an amount of the second gas supplied to around the mold by the adjuster so as to make the concentration of the first gas around the mold in the processing in the second region become larger than in the processing in the first region.

10. The apparatus according to claim 8, wherein the first gas is oxygen, and the second gas is a gas lower in oxygen concentration than air.

11. The apparatus according to claim 1, wherein the first gas is oxygen.

12. The apparatus according to claim 1, wherein the first region is a region that does not include an outer edge portion of the substrate, and the second region is a region that includes the outer edge portion.

13. A shaping method of performing, for each of a plurality of regions on a substrate, processing of aligning a mold with the substrate while the mold is in contact with a composition on the substrate and then curing the composition to shape the composition,
wherein the composition has a property of being inhibited from undergoing a curing reaction by a first gas,
the plurality of regions includes a first region where the processing is performed while a concentration of the first gas around the mold is adjusted to a first concentration and a second region where the concentration of the first gas around the mold is adjusted to a second concentration larger than the first concentration,
the processing includes preliminary exposure that increases a viscosity of the composition by causing the light irradiator to irradiate the composition with light for the alignment, and
the preliminary exposure in the second region is larger in an integrated irradiation amount of light to the composition than the preliminary exposure in the first region.

14. An article manufacturing method comprising:
shaping a composition on a substrate by using a shaping method defined in claim 13;
processing the substrate having the composition shaped in the shaping; and
manufacturing an article from the substrate processed in the processing.
